(19) United States
(12) Patent Application Publication
(10) Pub. No.: US 2014/0090234 A1
(43) Pub. Date: Apr. 3, 2014

(54) APPARATUS AND METHODS FOR MULTI-SCALE ALIGNMENT AND FASTENING

(71) Applicant: David Kazmer, North Andover, MA (US)

(72) Inventor: David Kazmer, North Andover, MA (US)

(73) Assignee: University of Massachusetts, Boston, MA (US)

(21) Appl. No.: 14/119,575

(22) PCT Filed: May 23, 2012
(86) PCT No.: PCT/US12/39101

§ 371 Date: Nov. 22, 2013

Related U.S. Application Data
(60) Provisional application No. 61/489,136, filed on May 23, 2011.

(51) Int. Cl. H01L 23/544

(52) U.S. Cl. CPC H01L 23/544
USPC 29/592.1; 29/729

(57) ABSTRACT

Apparatus and methods for self-alignment and assembly of objects with micron-level and/or nanometer-level alignment accuracy. Mating alignment features spanning multiple length scales are disposed at surfaces of objects to be brought into contact. When the objects are pressed together, the alignment features guide alignment of the objects with respect to each other. The alignment features may provide retaining forces to hold the objects together. Micron-level and nanometer-level alignment accuracies may be achieved over large surface areas.

### FIELD OF THE INVENTION

The embodiments generally describe apparatus and methods for alignment and assembly of structures with micron and nanometer-level alignment accuracies.

### BACKGROUND

Significant advances have been made in micro- and nano-scale science and engineering; nanostructure assemblies have recently been designed with unique properties including photonic, electronic, and biosensing devices. (See, Guo, L. J., Recent progress in nanoimprint technology and its applications. Journal of Physics-London, Part D: Applied Physics, 2004. 37: p. 123-141.) There currently exist a number of common processes for nano-scale fabrication that include photolithography, electron-beam lithography, atomic force microscopy, ion beam milling, imprint lithography, as well as many other patterning and fabrication techniques with resolutions approaching and below 10 nm.

One of the most significant barriers to widespread use and commercialization of nanofabrication relates to the interfacing of multiple components and features across multiple length scales. For example, the unaided human can readily interact with and assemble devices with dimensions ranging from mm to m, but is largely incapable of manipulating and/or assembling devices with smaller length scales. Robotic systems can be used to easily and reliably manipulate and assemble features and components down to about 10 μm in size. However, finer interfacing typically requires more costly and esoteric closed loop positioning systems such as mask aligners and scanning electron microscopes having vibration isolation mechanisms and in some cases complex laser interferometric position sensors. The bulk, cost, and time-consuming operation of these instruments often preclude their use in mass production and assembly techniques. Further, instruments that can manipulate objects at the micron and/or nanometer scale are often not adapted to handle objects at larger length scales.

### SUMMARY

Described herein are techniques for performing alignment and optional fastening of multiple components across multiple length scales. The inventors have recognized and appreciated that mating alignment features spanning multiple length scales may be incorporated onto selected surfaces of objects to aid in the alignment and assembly of the objects requiring micron-level and/or nanometer-level alignment accuracy. In some cases, the alignment features may guide alignment of the assembled objects down to the nanometer length scale, even when assembled by hand or using low-tech assembly instrumentation. In some embodiments, the alignment features may be embodied in a fractal pattern, though other patterns may be used. Further, the alignment features may provide a retaining force that can hold the assembled objects together. The simplicity of the alignment technique and diversity of its application will be appreciated by those skilled in the art of micro- and nano-scale fabrication.

One aspect of the inventive embodiments includes a first plurality of alignment features disposed at a first surface of a first object. The first plurality of alignment features may comprise at least one first alignment feature comprising a three-dimensional structure having a first length scale as measured parallel to the first surface. The first plurality of alignment features may further comprise at least one second alignment feature comprising a three-dimensional structure having a second length scale as measured parallel to the first surface. The second length scale may be less than one-half the first length scale. Additionally, the first plurality of alignment features may be configured to mate with a plurality of corresponding second alignment features at a second surface of a second object.

Another embodiment includes a first object comprising a plurality of alignment features disposed at a first surface of the first object. The plurality of alignment features may comprise at least one first alignment feature comprising a three-dimensional structure having a first length measured parallel to the first surface, and at least one second alignment feature comprising a three-dimensional structure having a second length measured parallel to the first surface. The plurality of alignment features may be configured to mate with a plurality of corresponding alignment features on a second surface of a second object, and the second length may be less than one-half the first length.

Also contemplated is a means for aligning a first object to a second object, wherein the means comprises mating a first plurality of alignment features to a second plurality of alignment features. The first and second plurality of alignment features may include mating alignment features of at least two different length scales.

A further aspect of the invention includes a method for aligning a first object to a second object. The method comprises an act of moving a first plurality of alignment features disposed at a first surface of the first object into mating contact with a second plurality of alignment features disposed at a second surface of the second object. In this method, the first plurality of alignment features comprises at least one first alignment feature comprising a three-dimensional structure having a first length measured parallel to the first surface, and at least one second alignment feature comprising a three-dimensional structure having a second length measured parallel to the first surface. The first plurality of alignment features may be configured to mate with the second plurality of alignment features, and the second length may be less than one-half the first length.

According to another embodiment, a method for aligning a first object to a second object further includes holding the first and/or second object in at least one fixture that permits displacement and/or rotation of the first and/or second object with respect to the at least one fixture; moving the first object and/or second object so that the first surface moves toward the second surface; engaging the at least one first alignment feature to achieve a first alignment accuracy between the first and second objects; and engaging the at least one second alignment feature to achieve a second alignment accuracy between the first and second objects. In various embodiments, the second alignment accuracy is more accurate than the first alignment accuracy.

Yet another aspect of the invention includes a die for replicating alignment features. The die may comprise a plurality of first alignment features, each one of the first alignment features comprising a three-dimensional structure having a first length scale as measured parallel to a first surface of the die. The die further includes a plurality of second alignment features, each one of the second alignment features comprising a three-dimensional structure having a second length scale as measured parallel to the first surface. The second length scale may be less than one-half the first length scale. The first and second plurality of alignment features may be configured to pattern features at a second surface of a first object that mate with a plurality of corresponding alignment features on a third surface of a second object.

It should be appreciated that all combinations of the foregoing concepts and additional concepts discussed in greater detail below (provided such concepts are not mutually inconsistent) are contemplated as being part of the inventive subject matter disclosed herein. In particular, all combinations of claimed subject matter appearing at the end of this disclosure are contemplated as being part of the inventive subject matter disclosed herein. It should also be appreciated that terminology explicitly employed herein that also may appear in any disclosure incorporated by reference should be accorded a meaning most consistent with the particular concepts disclosed herein.

The foregoing and other aspects, embodiments, and features of the present teachings can be more fully understood from the following description in conjunction with the accompanying drawings.

### BRIEF DESCRIPTION OF THE DRAWINGS

The skilled artisan will understand that the figures, described herein, are for illustration purposes only. It is to be understood that in some instances various aspects of the invention may be shown exaggerated or enlarged to facilitate an understanding of the invention. In the drawings, like reference characters generally refer to like features, functionally similar and/or structurally similar elements throughout the various figures. The drawings are not necessarily to scale, emphasis instead being placed upon illustrating the principles of the teachings. The drawings are not intended to limit the scope of the present teachings in any way.

FIG. 1 illustrates alignment of a first object with respect to a second object, according to one embodiment of the present invention.

FIG. 2 depicts mating alignment features of multiple length scales, according to one embodiment.

FIGS. 3A-3F depict plan views (3A-3D) and elevation views (3E-3F) of one embodiment of alignment features configured as a fractal pattern.

FIG. 4 illustrates aligned assembly of two objects, according to one embodiment.

FIGS. 5A-5D depicts elevation views of various alignment features that may be used in one or more embodiments of the invention.

FIGS. 6A-6C show plan views of a pattern of alignment features, according to one embodiment.

FIGS. 6D-6E illustrate elevation views of assembled objects having alignment features patterned as depicted in FIGS. 6A-6C.

FIG. 7 is a perspective view of an object having alignment features disposed at a first surface, according to one embodiment.

FIG. 8 illustrates one embodiment of two objects undergoing self-alignment, and is used as one example for theoretical considerations of the inventive alignment features and techniques.

FIGS. 9A and 9B represent one example of a theoretical model of normally distributed, uncorrected positional errors across piece 820, according to the example of FIG. 8.

FIG. 10A depicts a plan view of a surface having alignment features 1020, according to one embodiment.

FIG. 10B is a section view showing engagement or insertion of alignment features for purposes of a theoretical analysis, according to one embodiment.

FIG. 11A represents a grayscale plot of in-plane deflections experienced by regions near the alignment features after mating of the alignment features, according to one numerical example.

FIG. 11B represents contour plots of stresses in regions near the alignment features after mating of the alignment features, according to the example of FIG. 11A.

FIG. 12 illustrates a flow diagram of a method for aligning a first object and second object, according to one embodiment of the invention.

The features and advantages of the present invention will become more apparent from the detailed description set forth below when taken in conjunction with the drawings.

### DETAILED DESCRIPTION

Introduction

Apparatus and methods for accurately aligning and assembling objects are described. In overview, a plurality of alignment features may be disposed at a selected surface of each object to be assembled. The plurality of alignment features may include distinct structures having a first length scale and at least distinct structures having a second length scale. The second length scale may be significantly less than the first length scale, e.g., less than one-half or more. The plurality of alignment features on one surface of a first object may be configured to mate to, e.g., fit together with, a plurality of alignment features on one surface of a second object. The alignment features may physically and mechanically guide alignment of the first object with respect to the second object as the two objects are brought together. In some embodiments, the alignment features guide alignment of the objects to micron-level accuracies, and in some implementations to nanometer-level accuracies.

The inventor has recognized that incorporation of alignment features of multiple length scales at surfaces of objects to be assembled can provide a low-cost paradigm for achieving highly accurate alignment of assembled objects using simple assembly techniques. In some cases micron and/or nanometer-level alignment accuracy may be achieved via hand assembly. It will be appreciated by those skilled in the art of micro- and nano-fabrication that the embodiments described herein provide illustrative examples intended to teach various aspects of the invention. Additional variations and combinations that may be more complex have been considered, but are too numerous to include in this description.

The term “length scale” is used herein to refer to a characteristic size of an alignment feature. For example, an alignment feature having a length scale of 10 microns may have a maximum dimension, as measured in a direction parallel to the surface at which the structure is disposes, of about 10 microns.

The terms “about,” “substantially,” and “approximately” may be used to quantify a value or condition as being equal to or nearly equal to a target value within a factor of ±25%. In some embodiments the factor is ±20%. In some embodiments the factor is ±15%. In some embodiments the factor is ±10%. In some embodiments the factor is ±5%. In some embodiments the factor is ±2%. In some embodiments the factor is ±1%. In some embodiments the factor is ±0.5. In some embodiments the factor is ±0.2%. In some embodiments the factor is and ±0.1%.

The term “micron-level” is used herein to refer to a length scale between about 0.1 micron and about 100 microns.

The term “nanometer level” is used herein to refer to a length scale between about 0.1 nanometers and about 100 nanometers.

Apparatus for Micron and Nanometer-Level Alignment

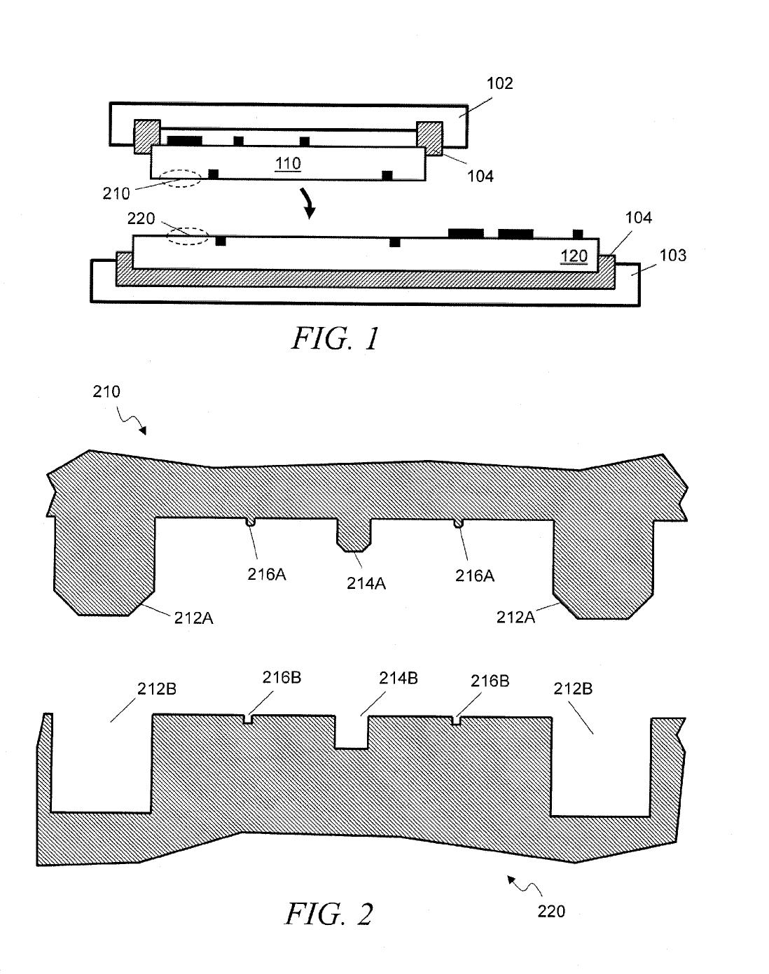

Referring now to FIG. 1 and FIG. 2, alignment and assembly of a first object 110 to a second object 120 is depicted according to one embodiment of the present invention. The second object 120 may be any structure configured to receive the first object 110. At least at one region 210 of the first object 110, there is disposed a first plurality of alignment features, e.g., as shown in the magnified view of FIG. 2. At least at one region 220 of the second object 120, there is disposed a corresponding plurality of alignment features, also shown in FIG. 2. The first plurality of alignment features may mate to, e.g., fit together with, the second plurality of alignment features when the first object is brought into contact with the second object. In this way, a product or process can be designed in which two components are aligned and optionally fastened.

Although FIG. 1 depicts the alignment features disposed in a single region 210 on the first object 110 and a single region 220 on the second object 120, in another embodiment, the alignment features may be distributed across a majority or all of a surface of object 110 that will contact with object 120. Similarly, the mating alignment features on object 120 may distributed across a majority or all of its surface that will receive object 110. The alignment features may be distributed uniformly, e.g., substantially in a repetitive pattern of uniform spacing, in some embodiments. In other embodiments, the alignment features may be distributed non-uniformly, e.g., limited to distinct regions on a contact surface. When distributed non-uniformly, the distinct regions may be located near a periphery of the contact surfaces of the objects to be assembled, or they may be located at selected locations across a contact surface, or a combination thereof.

As shown in FIG. 2, the plurality of alignment features 212A, 214A, 216A on the first object 110 may be configured to mate to the plurality of alignment features 212B, 214B, 216B on the second object 120. In this regard, the alignment features may include male- and female-type structures. In some embodiments, the alignment features may fit together easily, e.g., the male-type structure may be sized equal to or slightly less than its corresponding female-type structure. In some embodiments, the alignment features may be configured to provide an interference fit, or to provide a snap fit, e.g., the male-type structure may be sized slightly larger than the female-type structure. In some embodiments, alignment features of both male- and female-type structures may be disposed at a first surface (rather than all of one type as shown in FIG. 2) of an object 110, and corresponding male- and female-type structures may be disposed at a second surface of a second object 120.

It can be seen in FIG. 2, that the plurality of alignment features in each region 210, 220 includes alignment features of multiple length scales. In the illustrated embodiment, the alignment features are provided at three length scales. For example, features 212A, 212B may be of a first length scale, features 214A, 214B may be of a second length scale, and features 216A, 216B may be of a third length scale. There may be one or more alignment features at each length scale disposed at a surface. In various embodiments, each length scale corresponding to one or more alignment features differs from the other length scales of other alignment features disposed at the same surface. For example, a second length scale corresponding to one or more alignment features on a surface may differ from a first length scale corresponding to one or more other alignment features on the surface by a value within a range selected from the following group: from about ½ to about ⅓, from about ⅓ to about ¼, from about ¼ to about ⅕, from about ⅕ to about 1/10, from about 1/10 to about 1/20, from about 1/20 to about 1/40, from about 1/40 to about 1/80, and from about 1/80 to about 1/160.

For illustrative purposes in the example depicted in FIG. 2, the alignment features are provided in three length scales. The second length scale for features 214A, 214B is about ⅓ the length scale for features 212A, 212B. The third length scale for features 216A, 216B, is about ¼ the length scale for features 214A, 214B. The arrangement of alignment features should not be interpreted as being limited to that shown in FIG. 2. There may be more or fewer alignment features for each length scale. Additionally, there may be more or fewer length scales present.

When aligning and assembling the two objects, the first object 110 may be brought into close proximity with the second object 120, and the two pieces approximately aligned so that the largest alignment features 212A, 212B can mate. At least one of the two pieces may then be moved toward the other so that the largest alignment features begin to engage. As the pieces are brought together, the largest alignment features may guide self-alignment of the two pieces to a first level of alignment accuracy. In some embodiments, the largest alignment features first engage and impart in-plane alignment forces that tend to re-align one piece with respect to the other.

As the two pieces are brought closer, the next largest alignment features 214A, 214B may engage and guide self-alignment of the two pieces to a second level of alignment accuracy. The second level of alignment accuracy may be more accurate than the first level of alignment accuracy. Similarly, each successive size of alignment feature may engage and guide self-alignment of the two pieces to better alignment accuracy. As one example, the first level of alignment accuracy may be at the micron level, and the second level of alignment accuracy may be at the micron level. A final level of alignment accuracy may be at the nanometer level in some embodiments.

FIG. 1 also depicts apparatus 102, 103 that may be used to retain the first object 110 and second object 120 as they are aligned and assembled. Either apparatus 102, 103, or both, may comprise positioning equipment, e.g., micropositioners. Each apparatus may include a fixture for holding the object. The fixture on one or both of the apparatuses may include a flexible component 104 that permits displacement and/or rotation of the first and/or second object with respect to the respective retaining fixture. For example, the material 104 may be flexible or semi-rigid that will allow for small rotations and small displacements of the object with respect to its retaining fixture and/or positioning apparatus. The small rotations may be any value less than about 10 milliradians, and the small displacements may be any value less than about 1 millimeter. In some embodiments, the small rotations may be any value less than about 1 milliradian, and the small displacements may be any value less than about 100 microns. In some embodiments, the retaining fixture may include flexural members of the same material configured such that the retaining fixture and object mounted thereon may rotate or displace by small amounts with respect to its positioning apparatus. It will be appreciated that the incorporation of flexural members or material into the positioning apparatus provides in-plane compliance and permits the first object 110 to self align to the second object 120 under guidance from the plurality of alignment features 212, 214, 216.

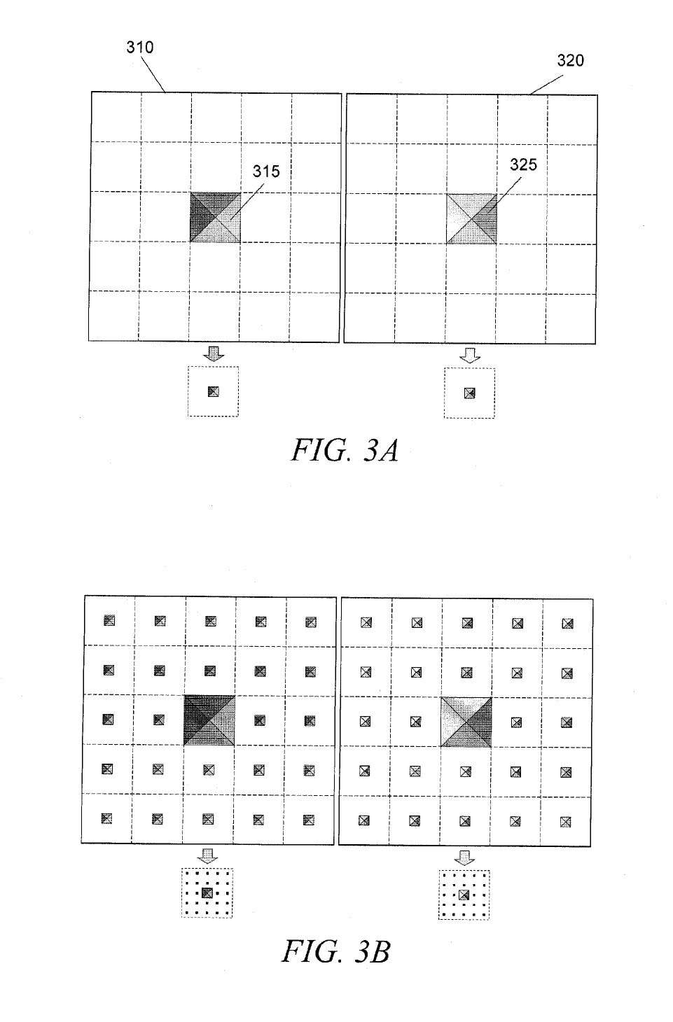

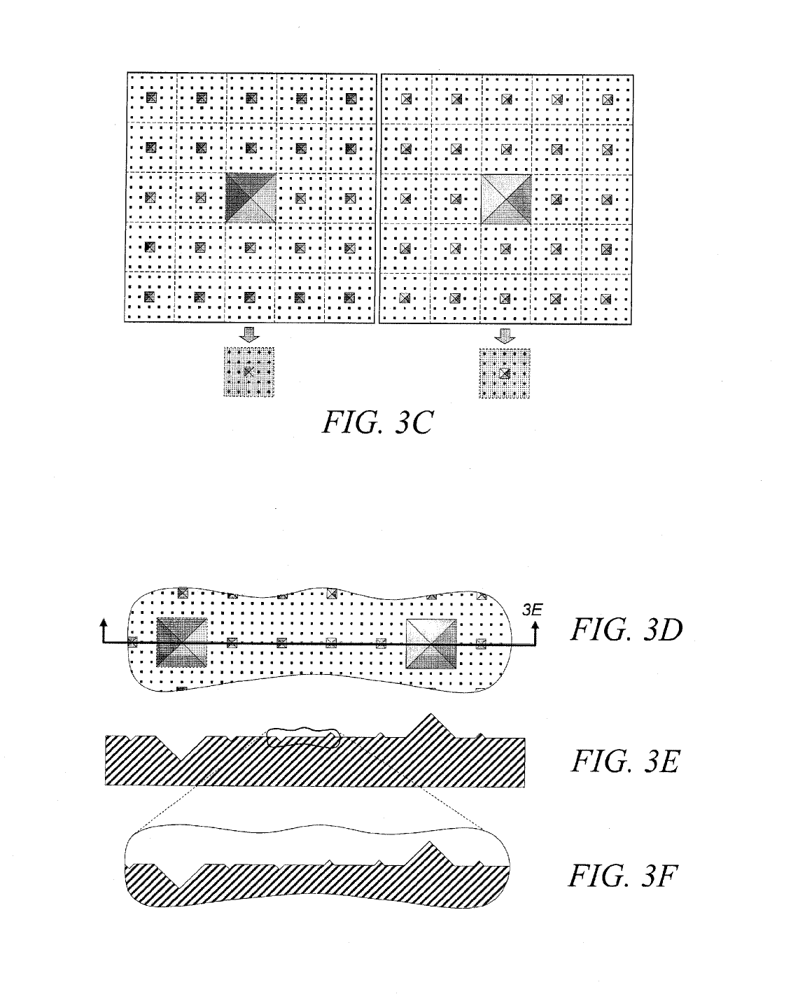

FIGS. 3A-3C shows a top down view of two regions 310, 320 that are designed to align with and mate to each other, according to one embodiment. The right hand illustration in FIG. 3A shows a (male) pyramidal protrusion 325 that engages a (female) pyramidal recess 315 shown in the left hand figure. The inclined surfaces of the pyramids are configured to allow lateral and vertical repositioning of an object on which the alignment features are disposed in the event of misalignment as the corresponding alignment features are mated in a top-down fashion (normal to the plane of the drawing).

In some embodiments, the alignment features may be arranged as a fractal pattern. For example, each region 310, 320 and its respective alignment feature shown in FIG. 3A can be taken as a pattern generator for smaller regions, e.g., regions that are a fraction of the size of regions 310, 320. In the illustrated non-limiting example, each region is divided into 25 smaller sub-regions, and the parent pattern may be scaled for repeating in the empty sub-regions. The scaled parent region is shown below the downward pointing arrows. The filling of the empty sub-regions is depicted in FIG. 3B.

In a fractal sense, it will be appreciated that the large scale features (5 units by 5 units) shown in FIG. 3A may be used for alignment on a large scale, and can serve as a generator for smaller features and finer alignment functionality at smaller scales. The smaller scaled features can provide local positioning and/or fastening on a smaller scale.

One advantage of the inventive alignment features and method may follow from the larger features serving to align the components or objects at larger scales and with large initial in-plane alignment forces before the smaller alignment features of the components are engaged. In this way, gross misalignments on larger scales are avoided which would otherwise cause the destruction of smaller features upon attempted mating. Furthermore, further iterations to smaller size scales can be used to provide even finer control as illustrated in FIG. 3C. In this way, alignment of multiple features can be ensured at multiple length scales and without special high-accuracy alignment equipment.

In some embodiments, the alignment features are configured such that the in-plane alignment forces totaling from a set of alignment features is less than the alignment forces totaling from the next smaller set of alignment features. For example, the total cross-sectional area of a set of alignment features may be less than the total cross-section area of the next smaller set of alignment features. For such a configuration, the alignment forces of a set of alignment features may dominate over the alignment forces of the next larger set of alignment features.

In some implementations, the alignment features are configured such that the alignment forces totaling for a set of alignment features is approximately equal to the alignment forces totaling from the next smaller set of alignment features.

FIGS. 3E-3F show cross sectional views through an enlarged section of one embodiment of the invention depicted in FIG. 3D. As shown, larger chamfered features are used to locate on a large scale while successively smaller features are used to locate features on successively smaller length scales. In this embodiment, both male and female-type alignment features may be provided on a same object.

In some embodiments, a die may be used to pattern the alignment marks. The die may be made from a rigid material, e.g., a metal, ceramic, or crystalline material. The die may be manufactured by ion milling, and may comprise, for example, a material selected from the following group: aluminum, copper, tungsten, molybdenum, silicon, diamond, silver, cobalt, carbon, chrome, ferrous metals, and their alloys. The die may include alignment features of both male and female type, and may be used to imprint the alignment features into a softer material, e.g., a soft metal or any type of polymer. In some embodiments, a first die may include alignment features to be patterned on a first object, and a second die may include corresponding mating alignment features to be patterned on a second object. In certain embodiments, a single die may be used to pattern mating alignment features on a first object and on a second object.

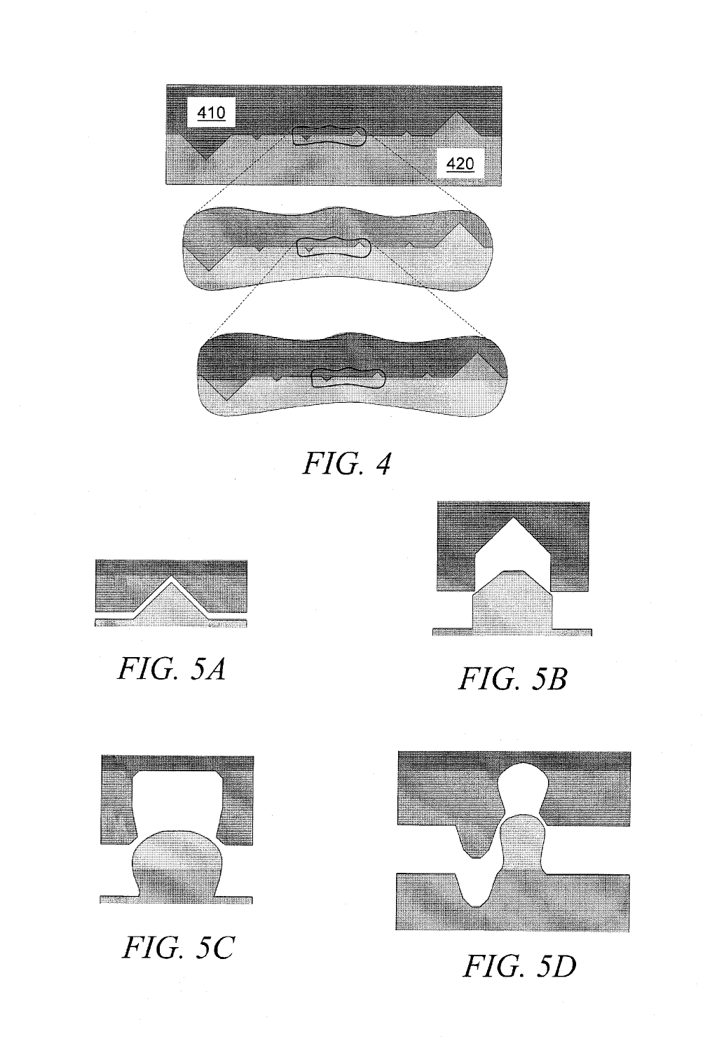

FIG. 4 can be used to illustrate alignment of a first object 410 to a second object 420. As illustrated, the first object is aligned with and in contact with the second object. In some embodiments, a majority of the surfaces of the first and second objects may be in intimate contact. In other embodiments, a portion of the surfaces, each containing the alignment features, may be in intimate contact with each other.

FIG. 4 can also be used to illustrate imprinting of alignment features onto an object 420 by a die 410. For imprinting, at least a portion of the die having alignment features is pressed into contact with the object so as to shape the surface of the object. The patterned object and die may be substantially planar, as depicted in the drawing, or may have curved surfaces. In the illustrated embodiment, the left-right symmetry of the alignment feature pattern permits a single die to be used to pattern alignment features on two objects that can align and mate to each other. For example, if two similar objects 420 were patterned with the die 410, a first object 420 could be rotated 180° and subsequently aligned and mated to the second object 420.

It will be appreciated that the inventive alignment features and methods may be used in many applications for alignment of multiple components in a process or product assembly. The components may include plastic or metal or ceramic parts, electrical circuits, microelectronics, optical components, integrated optical devices, compliant and non-compliant parts, workpieces and tooling, etc. For example, multiple components may be manufactured having the geometry shown in FIG. 4. The components may be molded by injection molding or imprint lithography or other processes. One component could then be mated to another to provide aligned assembly at multiple length scales.

Although the embodiments shown in FIG. 3 and FIG. 4 depict pyramidal alignment features, alignment features having other shapes are also contemplated. FIGS. 5B-5C show additional designs of alignment features providing different alignment and assembly functionality. Indeed, the shape and section of the mating features may be designed to best meet the application requirements, as further described below with examples relating to section, shape, and fractal pattern. The optimal selection of the mating geometry and spacing depends on the application requirements, application geometry, material properties, and other factors. In general, there is a trade-off between alignment performance and other considerations in which larger and more numerous mating features will provide improved alignment. However, larger and more numerous alignment features will not only require more complex tooling but also consume more of the usable surface area desired for other application requirements. As such, one of ordinary skill in the art may choose to optimize the number, size, geometry, and placement of the mating features. One of ordinary skill in product or process design will understand their application requirements and how to adapt these embodiments for their own purposes according to well established design principles.

With regard to the feature section, a pyramidal section as shown in FIG. 5A may provide large chamfered edges to correct for relatively large misalignments. The inclined angle in these examples is 45 degrees, but other angles may be selected to determine the height of the protrusion, depth of the recess, coefficient of friction, insertion forces, and resulting stresses in the mated components.

In some embodiments, the protrusion and corresponding recess need not have the same section or profile. For example, the protrusion may have a flat or rounded front surface rather than coming to a point or leading edge. Such a design will tend to reduce potential for damage to the protrusion or other components prior to assembly.

Furthermore, the size of the protrusion and recess need not match. For example, it may be desirable to design the protrusion to have a slightly larger width than its matching recess. In such a case, the material around the recess will experience tensile stresses while the material in the protrusion will experience compressive stresses upon assembly. The resulting stress will tend to hold mating pieces together. Such a design is known as a press fit or interference fit and is readily amenable to traditional engineering analysis techniques. FIG. 5B illustrates one embodiment of an alignment feature that may provide an interference fit when the alignment features are mated. As previously indicated, the relative sizes of FIG. 5B are exaggerated to illustrate the concept of a press fit and are not intended to represent the actual scale in an application.

Alternatively, the features may be designed to provide a snap fit type geometry in which an undercutting geometry is provided in the recess and/or protrusion to retain the protrusion in the recess after assembly. FIG. 5C illustrates another embodiment of an alignment feature that may provide snap fitting characteristics.

In some embodiments, the alignment features may include a combination of structures, as depicted in FIG. 5D. For example, each alignment feature may include a snap-fit structure and a tapered structure. The snap-fit structures may provide retention of the work pieces as well as an initial coarse alignment, and the tapered structures may provide a finer alignment accuracy as the pieces are moved together.

There is no requirement that the same feature generator or repeated pattern be used at every length scale for a plurality of alignment features. For example, in one embodiment snap-fit features as depicted in FIG. 5A may be used for the largest alignment features. The snap-fit features may be designed to have a “loose” fit, such that they provide an initially large alignment force that decreases as the two objects are brought closer together. The decreasing alignment forces from the snap-fit alignment structures may be overtaken by alignment forces from the next smaller size of alignment features, which may be pyramidal features as depicted in FIG. 5A for example. A yet smaller size of alignment features may comprise press fit features exhibiting strong alignment forces as shown in FIG. 5B for example. In this manner, alignment forces and stresses may be distributed in a selected distribution among the alignment features of different length scales. For example, the shear stresses may be substantially equal for every alignment feature, regardless of length scale, or in some implementations, the shear stresses may be designed to be within acceptable limits for every alignment feature. Also, in some embodiments, the patterning accuracy for the larger alignment features can be less than the patterning accuracy for the smaller alignment features, which may relax the fabrication requirements for the alignment features. In some implementations, the patterning accuracy of alignment features of one length scale be sufficient that upon their assembly they roughly align the next set of smaller alignment features.

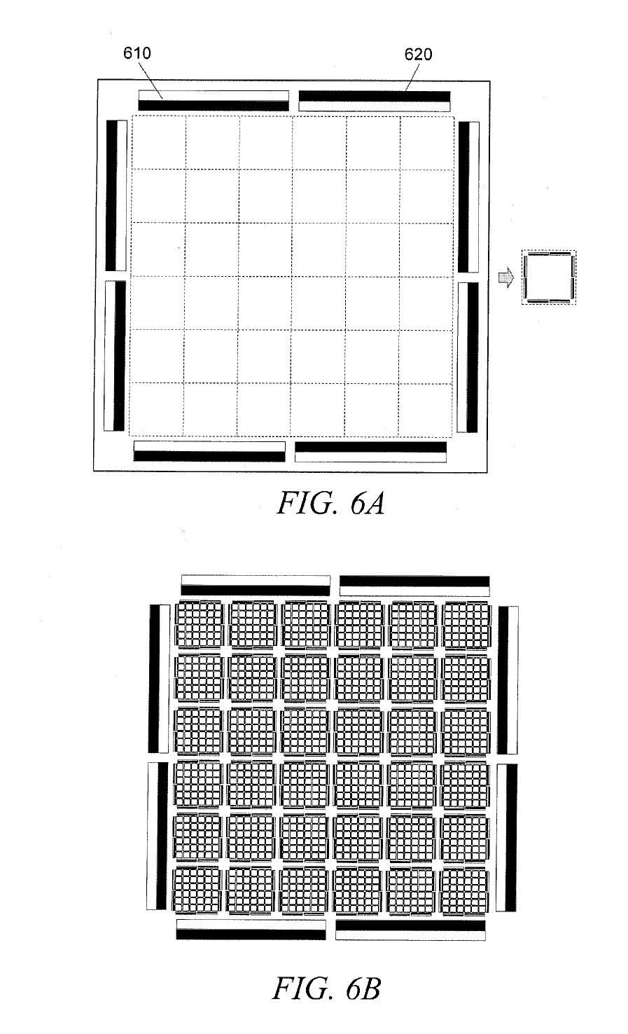

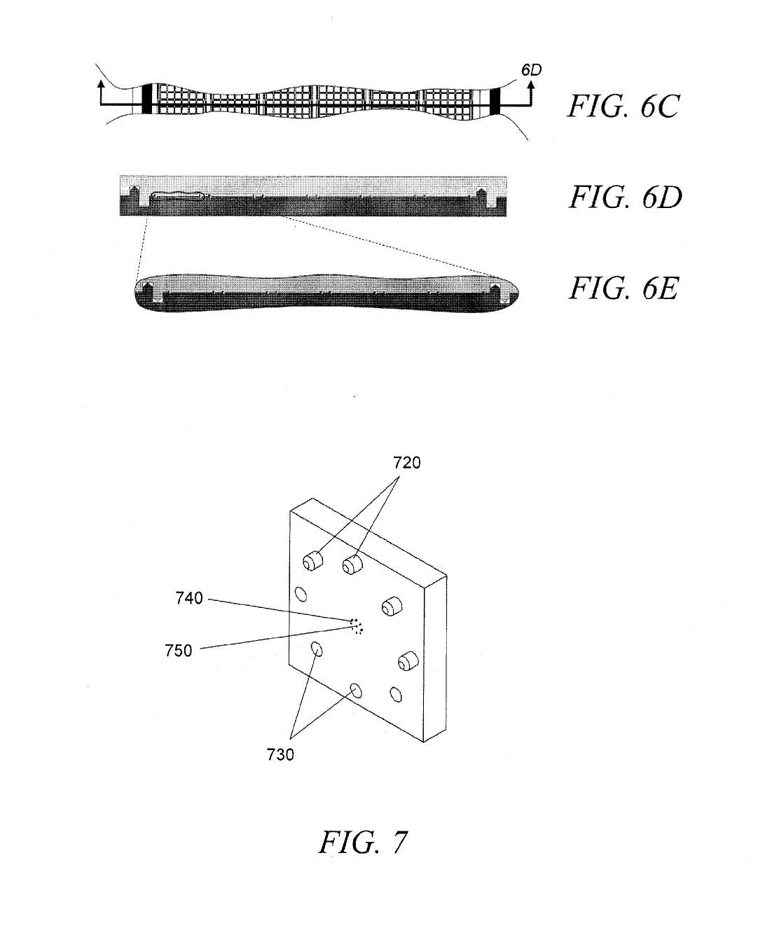

There is also considerable flexibility with regard to the shape and pattern of the mating features. For example, one embodiment may use rectangular shaped mating features 610, 620 to provide for improved alignment in the direction normal to the longer edge of the mating features, as depicted in FIGS. 6A-6E. In this example, the embodiment shows rectangular adjacent male and female features near the periphery of a region with an internal repeating pattern.

When the pattern shown in FIG. 6A is repeated three times, the pattern for self-aligning shown in FIG. 6B results. In this embodiment the internal areas between the interlocking or mating alignment features are explicitly aligned (as compared to the external area in the pyramidal embodiment shown in FIG. 3). Also, the spacing between the interlocking features provides a clearance or allowance space through which connections or conduits can be made to features having smaller length scales. Additionally, the pattern provides for symmetry and assembly across both the horizontal and vertical axes.

FIGS. 6D-6E show cross sections through two objects mated corresponding to the alignment feature pattern and sectional line depicted in FIG. 6C. As can be seen, larger prismatic features having chamfered leading edges are guided into corresponding rectangular recesses having square sections. Successively smaller patterns are used to guide the alignment and fastening at smaller length scales.

An embodiment is shown in FIG. 7 that comprises four cylindrical protrusions having a chamfered leading edge. These alignment features may be radially spaced and oppose four corresponding cylindrical cavities. The feature diameters may be provided in several distinct length scales. By way of example, the length scales may include alignment feature sizes in two or more combinations of length scales selected from the following list: between about 2 mm and about 0.2 mm, between about 0.2 mm and about 20 μm, between about 20 μm and about 2 μm, between about 2 μm and about 200 nm, between about 200 nm and about 20 nm. In one embodiment, the alignment features may be located approximately at a radius equal to 5 times the size of the alignment feature. As depicted in FIG. 7, the design may be used as a stamp in an imprint lithography process to produce polymeric components that can be subsequently self-aligned and assembled together.

As will be appreciated by those skilled in the art of microfabrication, there exists a large variety of alignment features and distribution patterns that may be used for self-alignment and assembly of components according to various aspects of the invention. Self-alignment accuracies at the micron and nanometer level may be possible using the embodiments described herein. Although the figures and related descriptions primarily address planar surfaces of objects, the alignment features may be disposed at non-planar surfaces in some implementations. For example, the alignment features may be disposed at convex or concave surfaces that mate to concave and convex surface, respectively.

With increased interest in micro- and nano-scale applications, there is an increasing diversity and capability of production processes. In some implementations of the present invention, all size features may be produced in a single process with the required or selected positional accuracies. Any number of fabrication processes may be used including, but not limited to, focused ion beam lithography, scanning electron-beam lithography, electron-beam microscopy. Alternatively, multiple processes can be used at different lengths with intermittent alignment. Multiple processes may further include milling and micro-milling, patterning with photolithography or shadow masking, deposition with chemical or physical deposition, chemical or reactive ion etching, and focused ion beam deposition and ablation.

One of ordinary skill in the art may appreciate that a build process for tooling might begin with large scale processes, such as milling, then move to smaller processes such as micro-milling, etc. Materials for tooling will vary with the application requirements and processing compatibility. Materials for tooling or for fabricating a die having the inventive alignment features may include aluminum, tungsten, silicon, copper, diamond, silver, platinum, cobalt, carbon, chrome, ferrous metals, and many others.

The concepts presented herein may be suitable for tooling having non-planar surfaces such as roll to roll and other multi-station processes including, without being limited to: forming, embossing, printing, deposition, metrology, and other processes. In such processes, a workpiece or product may consist of a plastic, metal, or other stock that is conveyed across multiple rolls or tools each with its own mating features at multiple length scales.

By using the described techniques, a workpiece may have one set of operations performed at a given processing station, then be removed and relocated to one or more subsequent operations where it is re-registered and further processing conducted. In this manner, embodiments of the invention may be applied to not only product assemblies containing components with multiple length scales, but also monolithic products consisting of multiple materials processed at multiple length scales. Potential applications include, but are not limited to: 1) lab on chip, 2) mechatronics, 3) solar cells and displays, 4) batteries, 5) semiconductors, and 6) other products and systems incorporating micro- and nano-structures.

In some embodiments, the inventive alignment marks may be used to align and/or retain a workpiece into a tooling fixture. For example and in reference to FIG. 1, piece 120 may be mounted in a tooling fixture and adapted to receive piece 110. Piece 110 may be a piece that will undergo a microfabrication process when self-aligned and mounted to piece 120. For example, piece 110 may be mounted for ion milling, ion-beam lithography, micro-milling, electron-beam microscopy, atomic force microscopy, or any other type of microfabrication process. In this way, a plurality of substantially identical workpieces 110 may be easily, rapidly and highly accurately aligned in a tooling fixture for subsequent processing.

Theoretical Considerations

For teaching purposes and without being bound to any particular model or theory, a brief theoretical analysis of certain aspects of self alignment according to one embodiment has been carried out. This analysis considers effects of in-plane variations and resulting stresses at the alignment features.

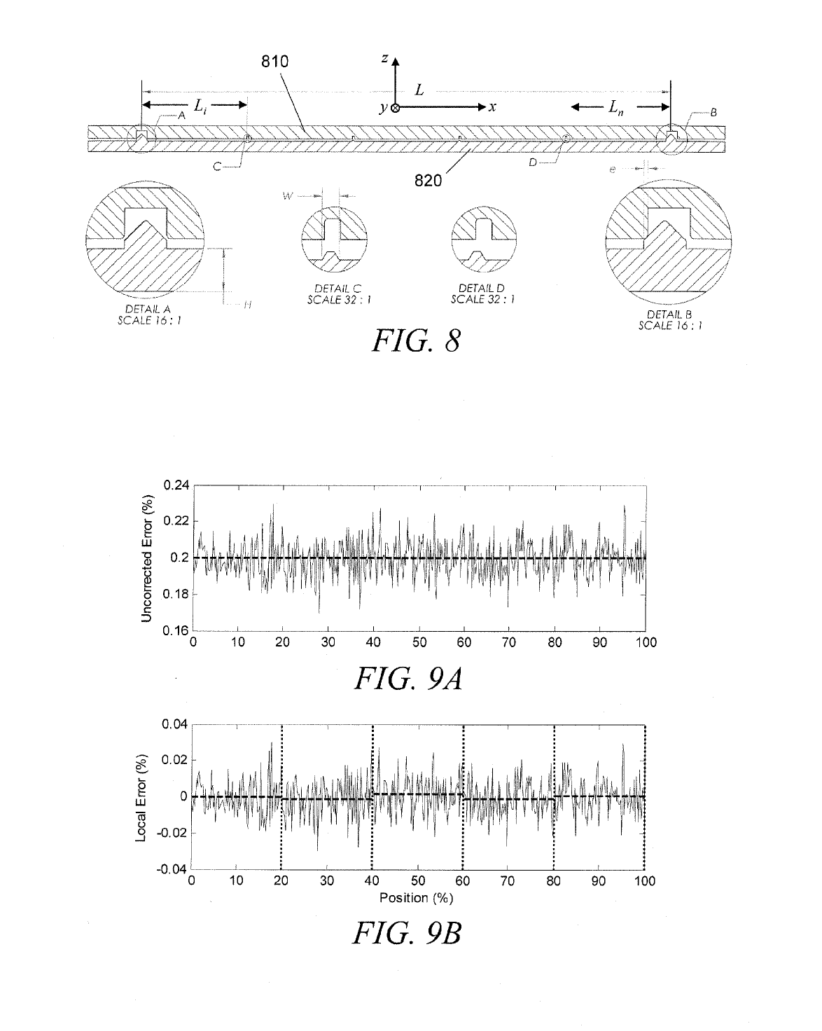

FIG. 8 shows a two part assembly having two sizes of alignment features distributed across contact surfaces of the two pieces 810, 820. There may be in-plane (x, y) variations across a length L of one or both pieces. These in-plane variations or distortions may be manifested as small errors in the positions of the alignment features, such that the alignment features on the first piece 810 do not match precisely the positions of the mating alignment features on the second piece 820 even if the two pieces were perfectly aligned with respect to each other. The positional errors may be due to any number of causes including variation in material properties, physical states during the manufacturing process, part compliance during assembly, instrument or sensor readings, different coefficients of thermal expansion, and others.

For example, there might be different dimensional errors between the two mating parts. As depicted in Detail B, the in-plane variations may give rise to a position error, e, at one of the larger alignment features. This error may not prevent the larger feature from completing its alignment upon insertion. However, the same error imposed at a smaller alignment feature could cause a collision and incomplete insertion or failed mating.

Furthermore, there may be different in-plane variations or error rates across sub-regions of the part (e.g., a sub-region of length Lᵢ in FIG. 8 may have larger or smaller in-plane variations than another sub-region at a different location on piece 820). As indicated in Detail C, the error in one sub-region may not cause the failure of the parts upon vertical assembly. However, at other locations such as shown at Detail D, the error may have accumulated across the length to an extent that failed mating would occur upon direct vertical assembly.

In some embodiments, the larger alignment features may correct an average error across a span of length L of a piece 820, so that the smaller alignment features can then correct the local errors in sub-regions denoted with a subscript i. For this analysis, it is assumed that piece 810 is perfectly rigid has no in-plane variations, i.e., all of its alignment features do not move and are precisely positioned at selected locations. In practice, both pieces 810, 820 may exhibit in-plane compliance.

Assuming that the position error e varies continuously across the length of a piece 820, an average error rate can be evaluated as:

ē=∫₀^{L}e(l)dl/L (1)

where e(l) is the local error rate at various length positions, l, across the part. For an average error, ē, and n different locations, the standard deviation of the error can be evaluated as:

$$σ = \sqrt{\frac{{\sum }_{i = 1}^{n} {( \overline{e} - {e}_{i} )}^{2}}{n - 1}} . \qquad ( 2 )$$

For example, consider an example in which the positional errors of alignment features are normally distributed with a mean of 0.2% and a standard deviation of 0.01%. FIG. 9A represents a plot of the distribution of positional errors across the length L of the piece 820. As indicated by the dashed line, the average uncorrected error is 0.2%. However, in some cases there may be significant variations within the region of length L in the normally distributed error.

In certain embodiments, a state of stress is imposed in one or both of the pieces 810, 820 by the larger alignment features that serves to reduce the average error. The resulting local error rates may then be expressed as:

ēᵢ=∫ᵢ₋₁^{L}^{ᵢ}(e(l)−ē)dl/(Lᵢ−Lᵢ₋₁) (3)

where the index i refers to different sub-regions across the piece 820. In some cases, the smaller alignment features need only correct the local error that has accumulated between their locations.

As shown in FIG. 9B, the distribution of the errors across the length of the piece 820 has not changed after the large alignment features have engaged and reduced the mean positional error. Once the average error has been mitigated, the local errors accumulate over short length distances. The dashed lines in FIG. 9B correspond to the average local error rates across the sub-regions Lᵢ to Lₙ shown in FIG. 8. In this particular example after compensation of the global average error (0.2%) by the large alignment features, the average errors in each sub-region become:

ēᵢ=[−0.000216% 0.00096% 0.00151% −0.00114% 0.00081%]

One of ordinary skill in the art would appreciate that systematic errors at one length scale (corresponding to a non-zero average error, ē) can be reduced or substantially corrected upon engagement of the larger alignment features and provide substantially smaller errors, ēᵢ, at smaller length scales.

The number and size of the alignment features selected for an application may be driven by the material properties, error distribution, and required tolerances of the application. For example, to compensate for an average error rate across a region of length L for piece 820, a strain ε must be induced in the piece for this region that is equal in magnitude to the average error. The nominal stress, σ, associated with this applied strain is:

σ=Eε=Eē (4)

where E is the elastic modulus of the material. For the example shown in FIG. 8, an uncorrected average error of 0.2% would require an induced strain of 0.2% to compensate for the error. If, for example, a polypropylene copolymer having a modulus of 896 MPa is being deformed, then the resulting stress would be 1.8 MPa.

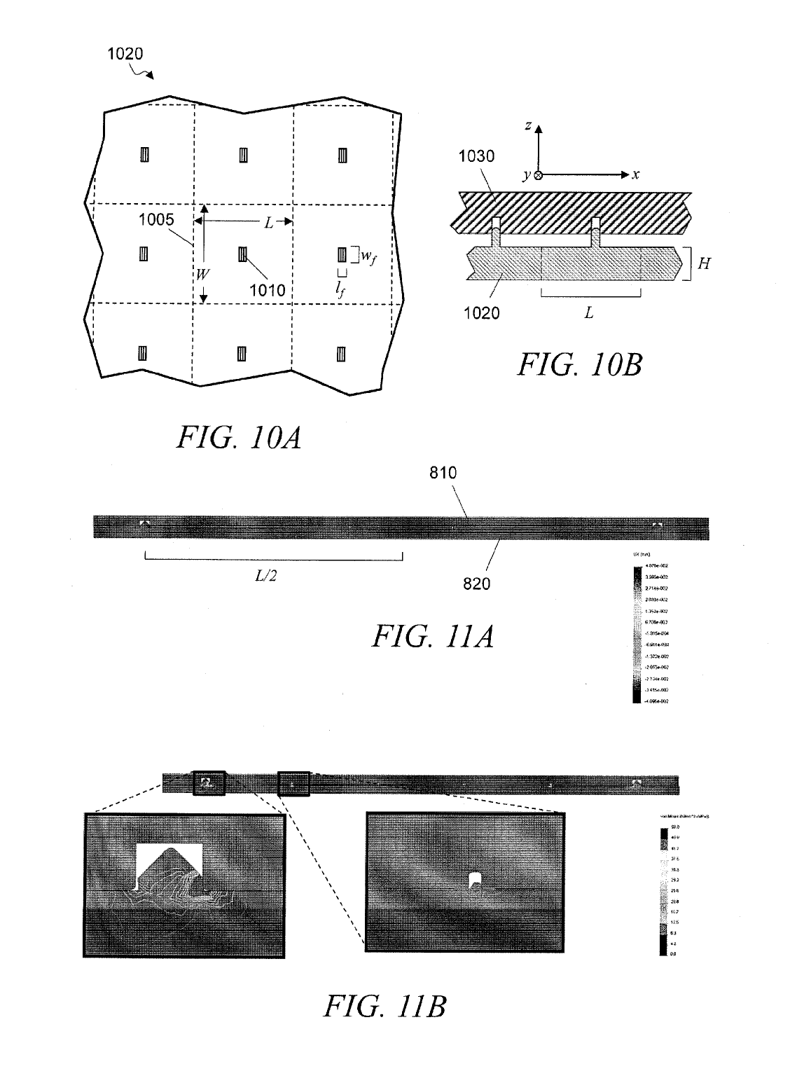

A lateral force, F, required to impart a compensating or error-reducing stress may be related to the cross-sectional area for the region L at which the stress is to be applied. With reference to the example shown in FIGS. 10A-10B and considering only x-directed errors, the compensating stress for a region 1005 of length L and width W may be taken as a stress exerted over a cross-sectional area in the piece 1020 having thickness H and a width W.

F=σA=σHW (5)

Knowing this compensating force enables one to consider, in a first approximation, the shear stresses acting on an alignment feature 1010 within the region. The nominal shear stress, τ, in the alignment feature 1010 can be defined as the required force, F, divided by a cross-sectional area of the alignment feature. If this feature has width, w_{f}, and length, l_{f}, as shown, then the shear stress in the alignment feature can be approximated to first order as:

$$τ = \frac{F}{{A}_{f}} = \frac{σ HW}{{w}_{f} {l}_{f}} . \qquad ( 6 )$$

The relation for shear stress on an alignment feature may also be expressed in terms of an average error for the region and the elastic modulus E of the material.

$$τ = \frac{\overline{e} EHW}{{w}_{f} {l}_{f}} \qquad ( 7 )$$

If the maximum sustainable shear stress τₘₐₓ, is known for piece 1020, then EQ. 7 can provide guidance in the design and distribution of alignment features for anticipated errors ē. In some embodiments, alignment features are designed and distributed such that τ is a fraction of τₘₐₓ, wherein the fraction is in a range selected from the following list: between about ½ and about ⅓, between about ⅓ and about ¼, between about ¼ and about ⅛, between about ⅛ and about 1/16, between about 1/16 and about 1/32, between about 1/32 and about 1/64, and between about 1/64 and about 1/128. If τ approaches τₘₐₓ, then the alignment features may permanently deform, break in an alignment process, or quickly fatigue and fail in repeated use of piece 1020.

When the geometry of the alignment features is determined, an areal yield ratio can be calculated. The areal yield ratio may be defined as the fraction of an object's surface area that is not consumed by mating alignment features. The yield Y of usable area remaining for non-alignment functions given multiple alignment stages can be computed as:

Y=(1−γ)ⁿ (8)

where γ represents the fraction of area in a unit region occupied by alignment features of a selected length scale for that region, and n represents the number of different length scales, alignment stages, or fractal pattern repetitions present. As one non-limiting example shown in FIG. 3 where four length scales of alignment features are provided, the yield evaluates to

Y=(1−5%)⁴=81.5%.

Referring again to FIGS. 10A-10B, the lateral deflection, δ, of an alignment feature can be estimated using static beam bending analysis:

$$δ ( z ) = \frac{Fz}{3 EI} \qquad ( 9 )$$

where I is the moment of inertia of the larger alignment feature and z is the distance between the base of the beam and the application of the lateral force, F.

In some embodiments, the global positional errors may be systematic, e.g., an effective slight magnification error between a first piece 810 and a second piece 820. In such cases, the accumulated stresses on large alignment features over large areas may require the width of the large alignment feature to approach a dimension that is approximately equivalent to or within an order of magnitude of the height H of the piece to be corrected.

The mechanics of the smaller alignment features in a sub-region are similar. However, the applied force and resulting deflection of the smaller alignment features are driven by the residual stresses required to correct the local sub-region errors ēᵢ after the larger global error has been compensated. The corresponding stress σₛ and shear stress τₛ for alignment features in a sub-region may be expressed as:

$$\begin{matrix}{σ}_{s} = E {\overline{e}}_{i} & ( 10 ) \\ {τ}_{s} = \frac{{\overline{e}}_{i} {EH}_{s} {W}_{s}}{{w}_{fs} {l}_{fs}} & ( 11 )\end{matrix}$$

where the subscript s is added to denote the respective quantities for the sub-region.

For the example depicted in FIG. 8 having an error that is normally distributed with a mean of 0.2% and a standard deviation of 0.01%, the global average error is 0.2% but the local errors ēᵢ are on the order of 0.002%, a factor of about one thousand times smaller. As such, the smaller alignment features may have a width, w_{fs}, that is very small compared to the nominal thickness, H, of the piece 820 yet still provide local corrections in alignment without encountering excessive stress.

A large deformation structural simulation was conducted to demonstrate aspects of the theoretical analyses described above. For the example shown in FIG. 8, a polypropylene piece 820 was modeled having a thickness, H, and width of the larger alignment feature both equal to 1 mm. The larger alignment features were spaced 50 mm apart. Four smaller alignment features were designed with a base width of 0.2 mm, a lead angle of the 30 degrees relative to the vertical, and spaced at 10 mm intervals.

A second rigid piece 810 was modeled having female features with dimensional errors proscribed according to FIGS. 9A-9B. The distance between the larger rectangular channels was 50.1 mm, corresponding to an average error of 0.2% for the region L. The distances between the smaller alignment channels were set according to local errors selected as:

ēᵢ=[−0.000216% 0.00096% 0.00151% −0.00114% 0.00081%]

The resulting lateral deformations are shown in FIG. 11A, and indicate that the larger alignment features experience the greatest deformation required to overcome the initial average error. The imposed stresses are plotted in FIG. 11B, and suggest that the polypropylene body encounters significant local stress in the larger alignment feature but the magnitude of stresses are within the capability of the material. The smaller alignment features encounter relatively low stress while correcting for local errors.

Related Methods

Various methods may be practiced in accordance with the foregoing teachings. For example, according to one embodiment a method may include acts for self-aligning a first object to a second object, wherein the first and second objects include mating alignment features at multiple length scales as described above.

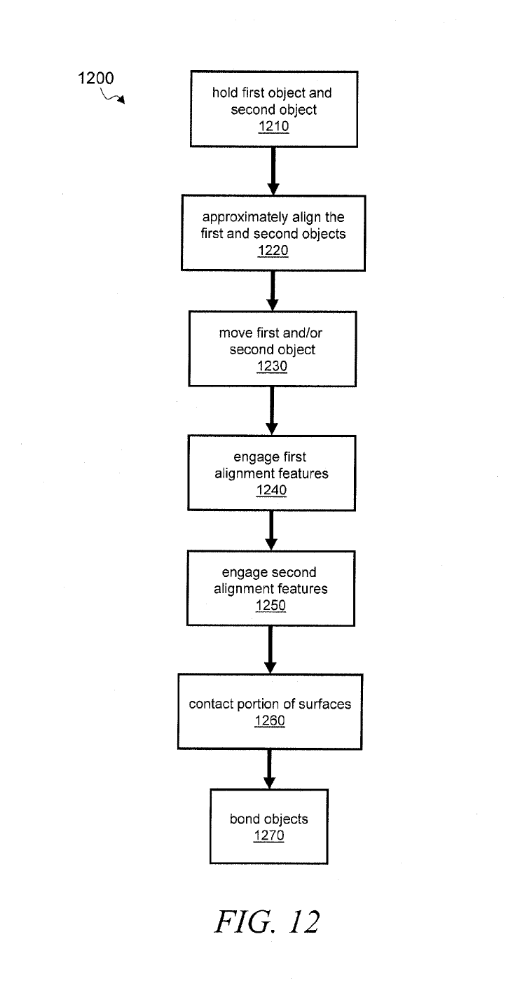

FIG. 12 depicts one embodiment of a method 1200 for aligning a first object to a second object. The first object may include a first plurality of alignment features disposed at a first surface of the first object, and the second object may include a second plurality of alignment features disposed at a second surface of the second object. The method may comprise an act holding 1210 the first and/or second object in at least one fixture that permits displacement and/or rotation of the first and/or second object. In some cases, the first object may be held rigidly, and the second object may be held in a manner that permits displacement and/or rotation of the second object with respect to the first object and/or the holding fixture. The first plurality of alignment features may comprise at least one first alignment feature comprising a three-dimensional structure having a first length scale measured parallel to the first surface and at least one second alignment feature comprising a three-dimensional structure having a second length scale measured parallel to the first surface. The first plurality of alignment features may be configured to mate with the second plurality of alignment features. In some embodiments, the second length scale is less than one-half the first length scale.

Method 1200 may further include acts of approximately aligning 1220 the first object with respect to the second object so that the first surface is near the second surface, and moving 1230 the first object and/or second object so that the first surface moves toward the second surface.

Method 1200 may further comprise acts of engaging 1240 the at least one first alignment feature of the first length scale to achieve a first alignment accuracy between the first and second objects, and engaging 1250 the at least one second alignment feature of the second length scale to achieve a second alignment accuracy between the first and second objects. In various embodiments the second alignment accuracy is more accurate than the first alignment accuracy.

In some embodiments, method 1200 includes an act of contacting 1260 at least a portion of the first surface with at least a portion of the second surface. Method 1200 may further comprise an act of bonding 1270 the first surface to the second surface. For example, one or both pieces include a thin adhesive surface coating that may be activated after self-aligned assembly to permanently bond the pieces together. The adhesive may be heat activated or optically activated or activate after a length of time. In a different embodiment, the act of bonding 1270 may be replaced with an act of processing (not shown) (e.g., micromilling, micropatterning, inspecting, ion-beam milling) of one or both of the objects.

### CONCLUSION

The section headings used herein are for organizational purposes only and are not to be construed as limiting the subject matter described in any way.

While the present teachings have been described in conjunction with various embodiments and examples, it is not intended that the present teachings be limited to such embodiments or examples. On the contrary, the present teachings encompass various alternatives, modifications, and equivalents, as will be appreciated by those of skill in the art.

While various inventive embodiments have been described and illustrated herein, those of ordinary skill in the art will readily envision a variety of other means and/or structures for performing the function and/or obtaining the results and/or one or more of the advantages described herein, and each of such variations and/or modifications is deemed to be within the scope of the inventive embodiments described herein. More generally, those skilled in the art will readily appreciate that all parameters, dimensions, materials, and configurations described herein are meant to be exemplary and that the actual parameters, dimensions, materials, and/or configurations will depend upon the specific application or applications for which the inventive teachings is/are used. Those skilled in the art will recognize, or be able to ascertain using no more than routine experimentation, many equivalents to the specific inventive embodiments described herein. It is, therefore, to be understood that the foregoing embodiments are presented by way of example only and that, within the scope of the appended claims and equivalents thereto, inventive embodiments may be practiced otherwise than as specifically described and claimed. Inventive embodiments of the present disclosure are directed to each individual feature, system, article, material, and/or method described herein. In addition, any combination of two or more such features, systems, articles, materials, and/or methods, if such features, systems, articles, materials, and/or methods are not mutually inconsistent, is included within the inventive scope of the present disclosure.

Also, the technology described herein may be embodied as a method, of which at least one example has been provided. The acts performed as part of the method may be ordered in any suitable way. Accordingly, embodiments may be constructed in which acts are performed in an order different than illustrated, which may include performing some acts simultaneously, even though shown as sequential acts in illustrative embodiments. Further, one or more of the method acts may be omitted in some embodiment, while in other embodiments additional acts may be added. In some implementations, one or more of the acts of a method may be replaced with one or more other acts.

All definitions, as defined and used herein, should be understood to control over dictionary definitions, definitions in documents incorporated by reference, and/or ordinary meanings of the defined terms.

The indefinite articles “a” and “an,” as used herein in the specification and in the claims, unless clearly indicated to the contrary, should be understood to mean “at least one.”

The phrase “and/or,” as used herein in the specification and in the claims, should be understood to mean “either or both” of the elements so conjoined, i.e., elements that are conjunctively present in some cases and disjunctively present in other cases. Multiple elements listed with “and/or” should be construed in the same fashion, i.e., “one or more” of the elements so conjoined. Other elements may optionally be present other than the elements specifically identified by the “and/or” clause, whether related or unrelated to those elements specifically identified. Thus, as a non-limiting example, a reference to “A and/or B”, when used in conjunction with open-ended language such as “comprising” can refer, in one embodiment, to A only (optionally including elements other than B); in another embodiment, to B only (optionally including elements other than A); in yet another embodiment, to both A and B (optionally including other elements); etc.

As used herein in the specification and in the claims, “or” should be understood to have the same meaning as “and/or” as defined above. For example, when separating items in a list, “or” or “and/or” shall be interpreted as being inclusive, i.e., the inclusion of at least one, but also including more than one, of a number or list of elements, and, optionally, additional unlisted items. Only terms clearly indicated to the contrary, such as “only one of” or “exactly one of,” or, when used in the claims, “consisting of,” will refer to the inclusion of exactly one element of a number or list of elements. In general, the term “or” as used herein shall only be interpreted as indicating exclusive alternatives (i.e. “one or the other but not both”) when preceded by terms of exclusivity, such as “either,” “one of,” “only one of,” or “exactly one of.” “Consisting essentially of,” when used in the claims, shall have its ordinary meaning as used in the field of patent law.

As used herein in the specification and in the claims, the phrase “at least one,” in reference to a list of one or more elements, should be understood to mean at least one element selected from any one or more of the elements in the list of elements, but not necessarily including at least one of each and every element specifically listed within the list of elements and not excluding any combinations of elements in the list of elements. This definition also allows that elements may optionally be present other than the elements specifically identified within the list of elements to which the phrase “at least one” refers, whether related or unrelated to those elements specifically identified. Thus, as a non-limiting example, “at least one of A and B” (or, equivalently, “at least one of A or B,” or, equivalently “at least one of A and/or B”) can refer, in one embodiment, to at least one, optionally including more than one, A, with no B present (and optionally including elements other than B); in another embodiment, to at least one, optionally including more than one, B, with no A present (and optionally including elements other than A); in yet another embodiment, to at least one, optionally including more than one, A, and at least one, optionally including more than one, B (and optionally including other elements); etc.

In the claims, as well as in the specification above, all transitional phrases such as “comprising,” “including,” “carrying,” “having,” “containing,” “involving,” “holding,” “composed of,” and the like are to be understood to be open-ended, i.e., to mean including but not limited to. Only the transitional phrases “consisting of” and “consisting essentially of” shall be closed or semi-closed transitional phrases, respectively, as set forth in the United States Patent Office Manual of Patent Examining Procedures, Section 2111.03.

The claims should not be read as limited to the described order or elements unless stated to that effect. It should be understood that various changes in form and detail may be made by one of ordinary skill in the art without departing from the spirit and scope of the appended claims All embodiments that come within the spirit and scope of the following claims and equivalents thereto are claimed.

What is claimed is:

1. A first object comprising a first plurality of alignment features disposed at a first surface of the first object, the plurality of alignment features comprising:
at least one first alignment feature comprising a three-dimensional structure having a first length measured parallel to the first surface; and
at least one second alignment feature comprising a three-dimensional structure having a second length measured parallel to the first surface, wherein the second length is less than one-half the first length,
wherein the first plurality of alignment features are configured to mate with a second plurality of corresponding alignment features at a second surface of a second object.

2. The object as claimed in claim 1, wherein the at least one second alignment feature comprises substantially a scaled replica of the first alignment feature.

3. The object as claimed in claim 1, wherein the at least one first alignment feature comprises a plurality of first alignment features distributed across an area of the first surface, and wherein the at least one second alignment feature comprises a plurality of second alignment features distributed across the area of the first surface.

4. The object as claimed in claim 3, wherein at least a portion of the plurality of first alignment features are configured to engage with mating alignment features on the second object before at least a portion of the plurality of second alignment features.

5. The object as claimed in claim 4, wherein the engaged portion of the plurality of first alignment features are configured to provide alignment for engagement of at least a portion of the plurality of second alignment features.

6. The object as claimed in claim 3, wherein at least a portion of the at least one first alignment feature protrudes from and/or is recessed into the first surface.

7. The object as claimed in claim 3, wherein at least a portion of the at least one second alignment feature protrudes from and/or is recessed into the first surface.

8. The object as claimed in claim 3, wherein the distribution of the first and the second alignment features comprises a fractal pattern.

9. The object as claimed in claim 3, wherein the first and/or second alignment features are distributed substantially uniformly across the first surface in a periodic array.

10. The object as claimed in claim 3, wherein the first and/or second alignment features are arranged in a plurality of localized areas at the first surface, wherein the localized areas contain a first density of the first and/or second alignment features and regions outside the localized areas containing second density of the first and/or second alignment features and the second density is less than one-half the first density.

11. The object as claimed in claim 1, wherein the first object is a die for replicating at least one of the first and at least one of the second alignment features on a surface of another object.

12. The object as claimed in claim 1, wherein the first object comprises a microfabricated component.

13. The object as claimed in claim 1, wherein the second dimension is less than the first dimension by a value selected from the following group: ⅓, ¼, ⅕, 1/10, 1/20, 1/50, and 1/100.

14. The object as claimed in claim 1, further comprising at least one third alignment feature comprising a three-dimensional structure having a third length parallel to the first surface, wherein the third length is less than one-half the second length.

15. The object as claimed in claim 14, wherein
the second length is less than the first length by a value selected from the following group: one-third, one-fourth, one-fifth, one-tenth, one-twentieth, one-fiftieth, and one-hundredth; and
the third length is less than the second length by a value selected from the following group: one-third, one-fourth, one-fifth, one-tenth, one-twentieth, one-fiftieth, and one-hundredth.

16. The object as claimed in claim 1, wherein each alignment feature is configured to withstand shear stresses in a unit area corresponding to the each alignment feature, the shear stresses resulting from alignment of the first surface to the second surface.

17. A method for aligning a first object to a second object, the first object comprising a first plurality of alignment features disposed at a first surface of the first object, the second object comprising a second plurality of alignment features disposed at a second surface of the second object, the first plurality of alignment features comprising at least one first alignment feature comprising a three-dimensional structure having a first length measured parallel to the first surface, and at least one second alignment feature comprising a three-dimensional structure having a second length measured parallel to the first surface, the second length being less than one-half the first length, the method comprising an act of:
moving the first plurality of alignment features disposed at the first surface of the first object into contact with the second plurality of alignment features disposed at the second surface of the second object.

18. The method of claim 17, further comprising contacting at least a portion of the first surface with at least a portion of the second surface.

19. The method of claim 17, further comprising bonding the first surface to the second surface.

20. The method of claim 17, wherein the at least one second alignment feature substantially comprises a scaled replica of the first alignment feature.

21. The method of claim 17, further comprising holding the first and/or second object in at least one fixture that permits displacement and/or rotation of the first and/or second object with respect to the at least one fixture.

22. The method of claim 21, wherein the act of moving comprises:
approximately aligning the first object with respect to the second object so that the first surface is near the second surface; and
moving the first object and/or second object so that the first surface moves toward the second surface.

23. The method of claim 21, wherein the act of moving comprises:
moving the first object and/or second object so that the first surface moves toward the second surface;
engaging the at least one first alignment feature to achieve a first alignment accuracy between the first and second objects; and
engaging the at least one second alignment feature to achieve a second alignment accuracy between the first and second objects, wherein the second alignment accuracy is more accurate than the first alignment accuracy.

24. A die for forming alignment features, the die comprising:
a plurality of first die features structured to form first alignment features, each of the first die features comprising a three-dimensional structure having a first length measured parallel to a first surface of the die; and
a plurality of second die features structured to form second alignment features, each of the second die features comprising a three-dimensional structure having a second length measured parallel to the first surface, wherein the second length is less than one-half the first length.

25. The die as claimed in claim 24, wherein the at least one second die feature comprises substantially a scaled replica of the first die feature.

26. The die as claimed in claim 24, wherein at least a portion of the first plurality of die features and/or at least a portion of the second plurality of die features protrude from the first surface.

27. The die as claimed in claim 24, wherein at least a portion of the first plurality of die features and/or at least a portion of the second plurality of die features is recessed into the first surface.

28. The die as claimed in claim 24, wherein the arrangement of the first and the second plurality of die features comprise a fractal pattern.

29. A plurality of alignment features disposed at a first surface of a first object, the plurality of alignment features comprising:
a first plurality of alignment features comprising three-dimensional structures, at least a portion of the first plurality of alignment features having a first length scale as measured parallel to the first surface; and
a second plurality of alignment features comprising three-dimensional structures, at least a portion of the second plurality of alignment features having a second length scale as measured parallel to the first surface,
wherein at least a portion of the first plurality and at least a portion of the second plurality of alignment features are configured to mate with a plurality of corresponding mating alignment features on a second surface of a second object.
